(19) United States
(12) Patent Application Publication
(10) Pub. No.: US 2014/0055189 A1
(43) Pub. Date: Feb. 27, 2014

(54) MIXER CIRCUIT, SEMICONDUCTOR DEVICE, RECEIVING CIRCUIT, RECEIVING DEVICE, AND COMMUNICATION DEVICE

(71) Applicant: KABUSHIKI KAISHA TOSHIBA, Tokyo (JP)

(72) Inventors: Masamichi SUZUKI, Tokyo (JP); Atsuhiro Kinoshita, Kanagawa (JP); Takao Marukame, Kanagawa (JP); Shouhei Kousai, Kanagawa (JP); Jun Deguchi, Kanagawa (JP)

(21) Appl. No.: 13/932,433

(22) Filed: Jul. 1, 2013

(30) Foreign Application Priority Data
Aug. 23, 2012 (JP) 2012-184209

(51) Int. Cl. H03D 7/14

(52) U.S. Cl. CPC H03D 7/1441
USPC 327/355

(57) ABSTRACT

According to an embodiment, a mixer circuit includes first transistors each having a charge storage layer, a second transistor, a group of first nodes, and an output node. The first transistors as a pair receive a differential signal having a first frequency. The second transistor receives a signal having a second frequency. The group of first nodes makes the charge storage layer of at least any one of the first transistors store charge during non-operation period during which the differential signal having the first frequency and the signal having the second frequency are not mixed and reduces loss of the charge during operation period during which those signals are mixed, to adjust a threshold voltage of at least any one of the first transistors from outside. The output node outputs a signal resulting from mixing the differential signal having the first frequency and the signal having the second frequency.

### CROSS-REFERENCE TO RELATED APPLICATIONS

This application is based upon and claims the benefit of priority from Japanese Patent Application No. 2012-184209, filed on Aug. 23, 2012; the entire contents of which are incorporated herein by reference.

### FIELD

An embodiment described herein relates generally to a mixer circuit, semiconductor device, receiving circuit, receiving device, and communication device.

### BACKGROUND

In related art, it is attempted to mount a high-frequency analog circuit and a digital circuit, which are often on separate chips, on one chip by using CMOS (complementary metal oxide semiconductor) technology. Furthermore, single balanced mixers and double balanced mixers utilizing pairs of MOS transistors, for example, are known among a large variety of mixer circuits.

There is, however, a problem that the characteristics of the analog circuit are deteriorated when the performance of the pairs of transistors varies.

### BRIEF DESCRIPTION OF THE DRAWINGS

FIG. 1 is a diagram illustrating an exemplary configuration of a single balanced mixer using a pair of nMOS transistors;

FIG. 2 is a diagram illustrating an exemplary configuration of a mixer circuit according to an embodiment;

FIG. 3 is a diagram illustrating an exemplary configuration of a transistor according to the embodiment;

FIGS. 4A and 4B are diagrams illustrating an outline of potential of a transistor according to the embodiment during writing and during circuit operation;

FIG. 5 is a diagram illustrating the direction of current during writing to a transistor according to the embodiment;

FIG. 6 is a diagram illustrating the direction of current during writing to a transistor according to the embodiment;

FIG. 7 is a graph illustrating an example of operation of SONOS after the amount of charge stored by a charge storage layer is changed according to the embodiment;

FIG. 8 is a graph illustrating the relationship between a change in threshold voltage Vth and voltage application time in the result illustrated in FIG. 7;

FIG. 9 is a diagram illustrating an exemplary configuration of SONOS where potentials can be isolated for each SONOS; and

FIG. 10 is a block diagram illustrating an outline of a receiving circuit of a communication device using a mixer circuit.

### DETAILED DESCRIPTION

According to an embodiment, a mixer circuit includes a plurality of first transistors, a second transistor, a group of first nodes, and an output node. The plurality of first transistors is used in a pair and receives a differential signal having a first frequency. The first transistors each have a charge storage layer. The second transistor receives a signal having a second frequency. The group of first nodes makes the charge storage layer of at least any one of the first transistors store charge during non-operation period during which the differential signal having the first frequency and the signal having the second frequency are not mixed and reduces loss of the charge during operation period during which the differential signal having the first frequency and the signal having the second frequency are mixed, so as to adjust a threshold voltage of at least any one of the first transistors from outside. The output node outputs a signal resulting from mixing the differential signal having the first frequency and the signal having the second frequency.

First, the circumstances that lead to a mixer circuit according to the embodiment being conceived will be described below with reference to the accompanying drawings.

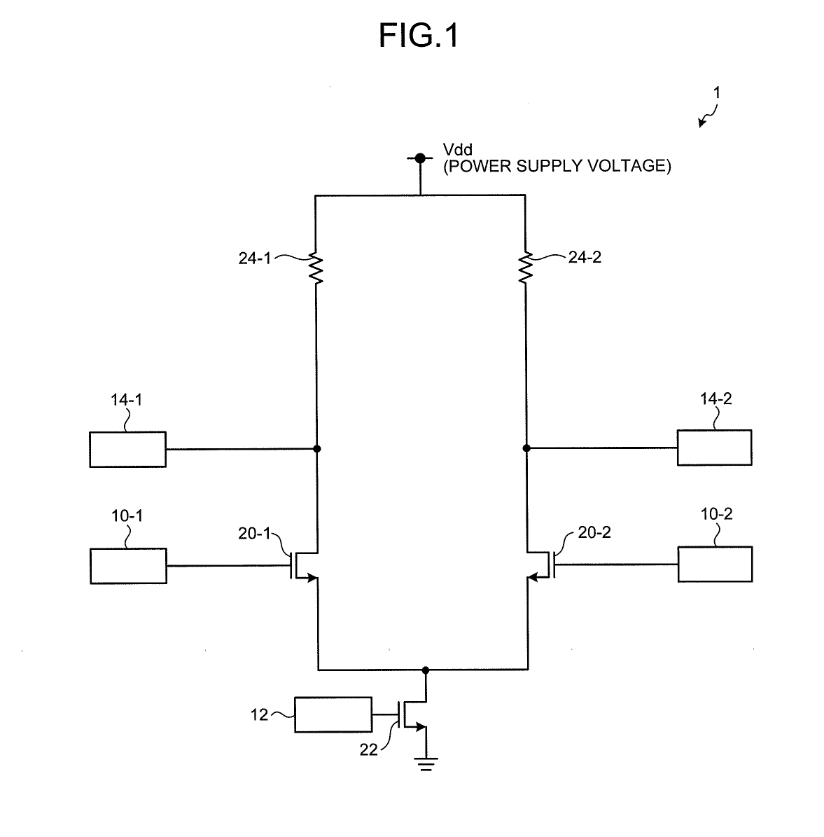

FIG. 1 is a diagram illustrating an exemplary configuration of a single balanced mixer 1 using a pair of nMOS transistors. As illustrated in FIG. 1, the single balanced mixer 1 includes differential input nodes 10-1 and 10-2, an input node 12, output nodes 14-1 and 14-2, nMOS transistors 20-1, 20-2 and 22, and load resistors 24-1 and 24-2.

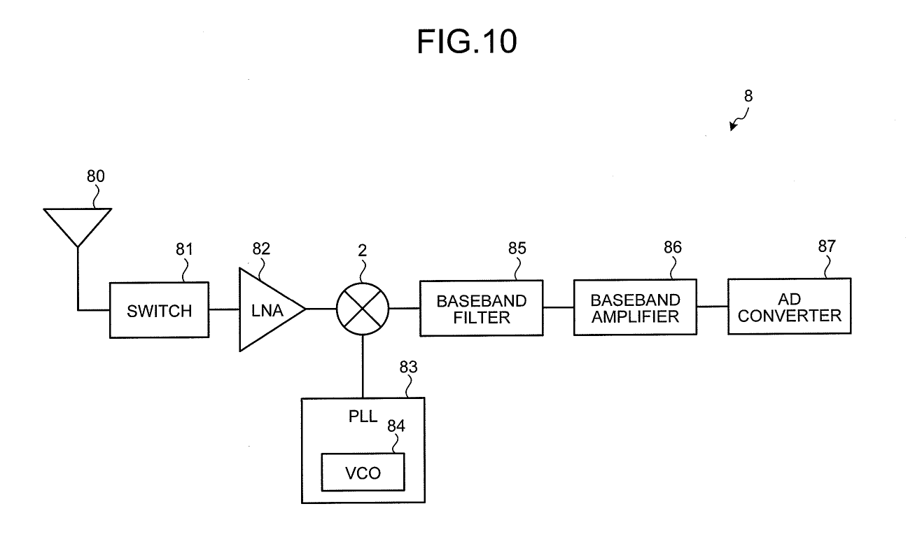

The single balanced mixer 1 is used for frequency conversion of RF (radio frequency) signals in a receiving circuit (see FIG. 10) of a wireless communication device, for example. For example, when the single balanced mixer 1 to which power supply voltage (Vdd) is applied is used in a direct conversion receiving circuit, a local signal LO (local oscillator) having a frequency f1 is differentially input to the differential input nodes 10-1 and 10-2 from a local oscillator. The differential signals of the local signal LO are respectively input to gate terminals of the nMOS transistors 20-1 and 20-2.

An RF signal having a frequency f2 that is equal to or very close to the frequency f1 is input to the input node 12. The RF signal is input to a gate terminal of the nMOS transistor 22. Note that the load resistors 24-1 and 24-2 lower the power supply voltage across the nMOS transistors 20-1 and 20-2, respectively.

The single balanced mixer 1 then mixes the differential signals of the local signal LO and the RF signal, and outputs differential signals having frequencies f2±f1 (if f2>f1; frequencies f1±f2 if f2<f1) from the output nodes 14-1 and 14-2. In the direct conversion method, signals having a frequency f2−f1, for example is used as a baseband signal.

If the nMOS transistors 20-1 and 20-2 and the load resistors 24-1 and 24-2 that are used in a pair have the same characteristics, it is possible to suppress even-order distortion including second-order distortion. It is, however, extremely difficult to make the characteristics of the nMOS transistors 20-1 and 20-2 and the load resistors 24-1 and 24-2 the same without variation in normal processes. Thus, the variation in characteristics existing in the nMOS transistors 20-1 and 20-2 and the load resistors 24-1 and 24-2 inevitably causes second-order distortion of an interfering wave in proximity in the baseband bandwidth, which deteriorates the SN ratio.

In general, when the random variation in threshold voltage Vth of a transistor is represented by σVth, a gate length is represented by L and a gate width is represented by W, σVth is proportional to −½ power of LW. Thus, the variation in Vth of the transistor is larger as the transistor is miniaturized. Accordingly, with the related art, it is difficult to make the variation smaller, and to improve the high-frequency characteristics by making L smaller and lower power consumption by making W smaller at the same time.

It is therefore attempted to reduce deterioration in the characteristics caused by the variation in transistors used in a pair regardless of the size of the transistors by means of a mixer circuit according to the embodiment.

### Embodiment

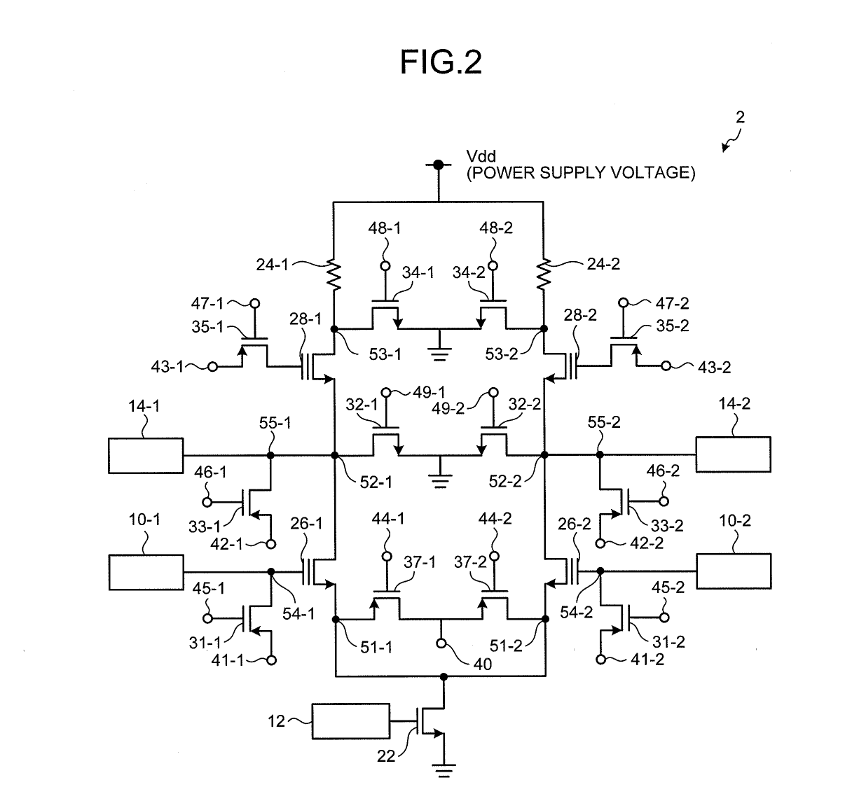

An example of the mixer circuit according to the embodiment will be described below with reference to the accompanying drawings. FIG. 2 is a diagram illustrating an exemplary configuration of a mixer circuit 2 according to the embodiment. For example, the mixer circuit 2 is a single balanced mixer having a configuration including transistors 26-1 and 26-2 instead of the nMOS transistors 20-1 and 20-2 illustrated in FIG. 1. Components of the mixer circuit 2 that are substantially the same as those of the single balanced mixer 1 illustrated in FIG. 1 will be designated by the same reference numerals. When certain one of a plurality of components such as the transistors 26-1 and 26-2 is referred to without specifying which of the components, the component may be simply referred to as a “transistor 26” or the like.

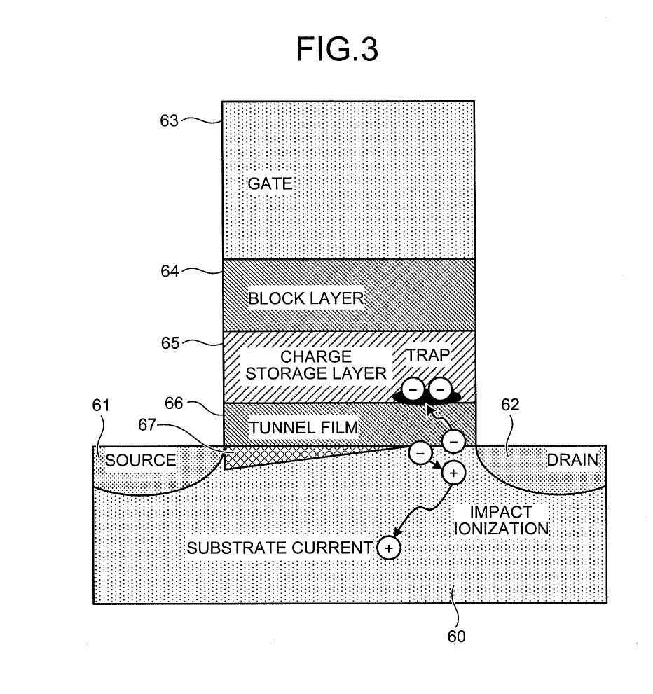

First, the transistor 26 will be described. FIG. 3 is a diagram illustrating an exemplary configuration of the transistor 26. The transistor 26 is a charge storage SONOS (silicon-oxide-nitride-oxide-semiconductor) transistor, for example. As illustrated in FIG. 3, the transistor 26 has a structure in which a source 61 and a drain 62 are formed on an Si (p-well) substrate 60 and a gate 63, a block layer 64, a charge storage layer 65, and a tunnel film 66 are stacked between the source 61 and the drain 62.

The tunnel film 66 is a silicon dioxide (SiO₂) film. The charge storage layer 65 is an insulating silicon nitride (SiN) film. The block layer 64 is, for example, a multi-layered film of silicon dioxide films or a silicon dioxide film and a silicon nitride film. Thus, the SONOS transistor (SONOS) stores charge in a trap in the nitride film (charge storage layer) that is an insulating film between silicon dioxide films and has a function of holding memory. The threshold voltage Vth of the SONOS changes with the amount of charge stored by the charge storage layer, and the value of the threshold voltage Vth is maintained when the amount of charge is maintained. The transistor 26 may be an MONOS (metal-oxide-nitride-oxide-semiconductor) or a transistor used for floating gate (FG) flash memory or the like.

An FG transistor employs a floating gate (Poly-Si) that is a conductor instead of an insulating charge storage layer (SiN). Since the floating gate is a conductor, the potential thereof is constant in the plane direction, and if a defect leading to charge leakage is caused in the tunnel film, the charge will be lost through the floating gate regardless of the position of the defect. In contrast, in a transistor such as an SONGS having an insulating charge storage layer, charge leakage is not caused unless the position of the defect in the tunnel film and the position of the trap in the charge storage layer match each other, and such transistors are therefore better in retention characteristics than the floating gate transistors.

Examples of the method for storing charge in an SONGS includes a method using FN tunnel injection and a method using a hot carrier generated by impact ionization (collision ionization) at the drain 62 of a channel 67 (N channel, for example) as illustrated in FIG. 3. In order to cause FN tunnel injection, a high voltage of about 10 V is typically required, and a booster circuit for boosting the power supply voltage is required. In contrast, the method using a hot carrier is advantageous is that writing (charge storage) is possible at the power supply voltage and a booster circuit is not required.

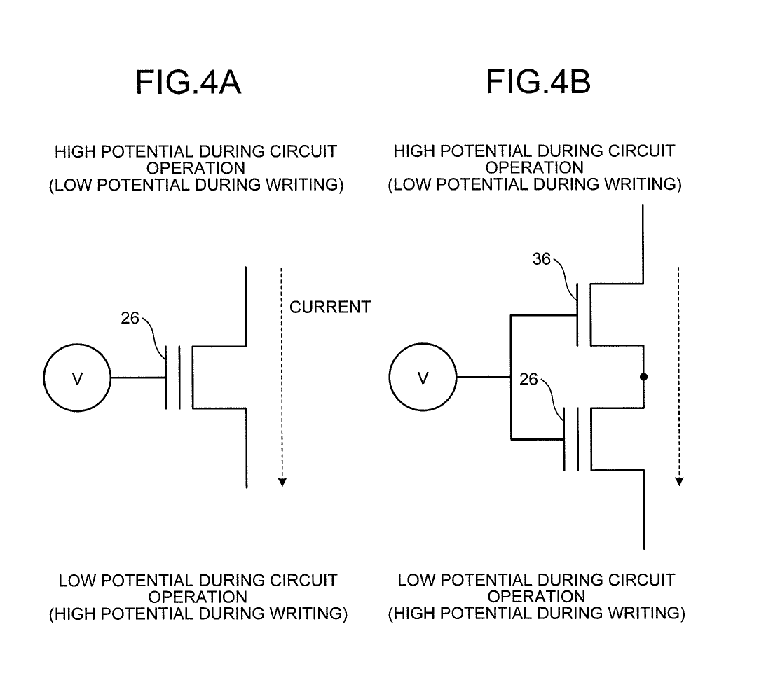

FIGS. 4A and 4B are diagrams illustrating an outline of potential of the transistor 26 during writing (charge storage) and during circuit operation. As illustrated in FIG. 4A, voltage is applied to the gate of the transistor 26, current flows between the drain and the source, and charge is thus stored. Note that the drain and the source of the transistor 26 are reversed during circuit operation and during writing. In other words, the drain and the source of the transistor 26 are replaced with each other. Furthermore, the drain voltage Vds of the transistor 26 is set to the power supply voltage, for example, during writing while the drain voltage Vds is set to be lower than the power supply voltage during circuit operation so as to prevent unintended writing to the charge storage layer.

Alternatively, as illustrated in FIG. 4B, the transistor 26 may be modified to have a configuration in which an nMOS transistor 36 sharing the gate terminal with the transistor 26 is connected to the high potential side during circuit operation. In this manner, in the transistor 26, a node at the high potential side during writing may become the low potential side during circuit operation and unintended writing to the charge storage layer may be prevented by voltage drop caused by the nMOS transistor 36 arranged at the high potential side during circuit operation.

The mixer circuit 2 (FIG. 2) is provided with transistors 28-1 and 28-2 respectively connected in series with the load resistors 24-1 and 24-2. The transistor 28 is an SONOS transistor having the same structure as the transistor 26 described above, for example. The transistors 28-1 and 28-2 are provided to resolve the variation in resistances of the load resistors 24-1 and 24-2 arranged as a pair. For example, since the threshold voltage Vth of the transistor 28 varies with the amount of change stored by the charge storage layer 65, the on-resistance thereof varies. It is thus possible to resolve the influence of the variation of the load resistors 24-1 and 24-2 by adjusting the on-resistance of at least either one of the transistors 28-1 and 28-2.

Furthermore, the mixer circuit 2 is provided with pMOS transistors 31-1, 31-2, 33-1, 33-2, 35-1, 35-2, 37-1, and 37-2. The mixer circuit 2 is also provided with nMOS transistors 32-1, 32-2, 34-1, and 34-2.

The mixer circuit 2 also includes nodes 40, 41-1 to 49-1, and 41-2 to 49-2 that can be connected to external circuits, and nodes 51-1 to 55-1, and 51-2 to 55-2 that are internal nodes. For example, potentials of the nodes 40, 41-1 to 49-1, and 41-2 to 49-2 can be arbitrarily changed in a range from the power supply voltage to ground by external control. Furthermore, the nodes 40, 41-1 to 49-1, and 41-2 to 49-2 are set to different potentials between during writing and during circuit operation.

The pMOS transistor 31 has a gate terminal to which the node 45 is connected, and a drain terminal, when the power supply voltage, etc., is applied to the node 41, connected to the gate terminal of the transistor 26 at the node 54.

The pMOS transistor 33 has a gate terminal to which the node 46 is connected, and a drain terminal, when the power supply voltage, etc., is applied to the node 42, connected to the output node 14 at the node 55.

The pMOS transistor 35 has a gate terminal to which the node 47 is connected, and a drain terminal, when the power supply voltage, etc., is applied to the node 43, connected to the gate terminal of the transistor 28.

The pMOS transistor 37 has a gate terminal to which the node 44 is connected, and a drain terminal, when the power supply voltage, etc., is applied to the node 40, connected to the drain terminal of the nMOS transistor 22 at the node 51.

The nMOS transistor 32 has a gate terminal to which the node 49 is connected, and a drain terminal connected to the node 52 between the transistor 26 and the transistor 28. Note that the potentials of the node 55 and the node 52 are equal.

The nMOS transistor 34 has a gate terminal to which the node 48 is connected, and a drain terminal connected to the node 53 between the low potential side of the load resistor 24 and the transistor 28.

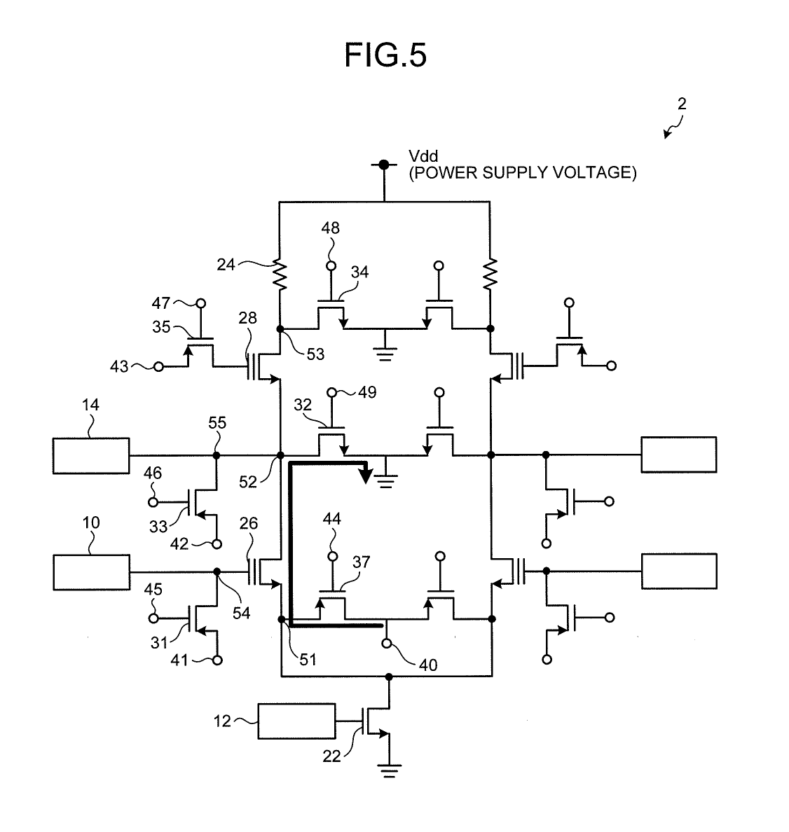

Next, an example of operation for writing (charge storage, threshold voltage adjustment) to the transistor 26 will be described. FIG. 5 is a diagram illustrating the direction of current during writing to the transistor 26. Note that the mixer circuit 2 illustrated in FIG. 5 is the same as the mixer circuit 2 illustrated in FIG. 2, and only one (left side in FIG. 5) of the differential input and the differential output is designated by reference numerals for simplification.

When the power supply voltage (3.3 V, for example) is applied to the node 40 and the node 44 is set to 0 V, the pMOS transistor 37 is turned on and the potential of the node 51 becomes approximately equal to the power supply voltage level. Furthermore, when the power supply voltage is applied to the node 49, the nMOS transistor 32 is turned on and the potential of the node 52 becomes approximately equal to the ground level.

When the power supply voltage is applied to the node 41 and the node 45 is set to 0 V in this state, the pMOS transistor 31 is turned on and voltage approximately equal to the power supply voltage is applied to the gate terminal of the transistor 26. The direction of current at this point is indicated by a thick arrow.

When the transistor 26 operates in this manner, a hot carrier is generated by impact ionization at the drain (on the side of the node 51) of the transistor 26, electrons are trapped in the charge storage layer 65 (FIG. 3) and the threshold voltage Vth changes. At this point, the voltage applied to the gate terminal of the transistor 26 may be at any level equal to or lower than the power supply voltage and may be changed as appropriate so as to efficiently cause impact ionization.

After changing the threshold voltage Vth of the transistor 26, the operator makes the mixer circuit 2 operate to measure second-order distortion. The operator then adjusts the threshold voltage Vth of the transistor 26 until the second-order distortion during circuit operation of the mixer circuit 2 is reduced to a desired value. In other words, the deterioration in the characteristics due to variation of the transistors 26-1 and 26-2 can be reduced by adjusting the threshold voltage Vth of at least either one of the transistors 26-1 and 26-2. Note that the adjustment of the threshold voltage Vth is not limited to that by actually measuring the second-order distortion but may be performed by other methods such as by measuring the threshold voltage Vth directly.

As described above, the threshold voltage Vth changes with the amount of charge stored by the charge storage layer 65, and the value of the threshold voltage Vth is maintained when the amount of charge is maintained. Accordingly, when the mixer circuit 2 operates after the threshold voltage Vth is adjusted, potentials that do not allow writing to the charge storage layer 65 of the transistor 26 are set at the nodes 51, 52 and 54. For example, in relation to the transistor 26, a node that is a source is set to 0 V, a node that is a drain is set to 0.1 V, and a node that is a gate is set to 0.8 V.

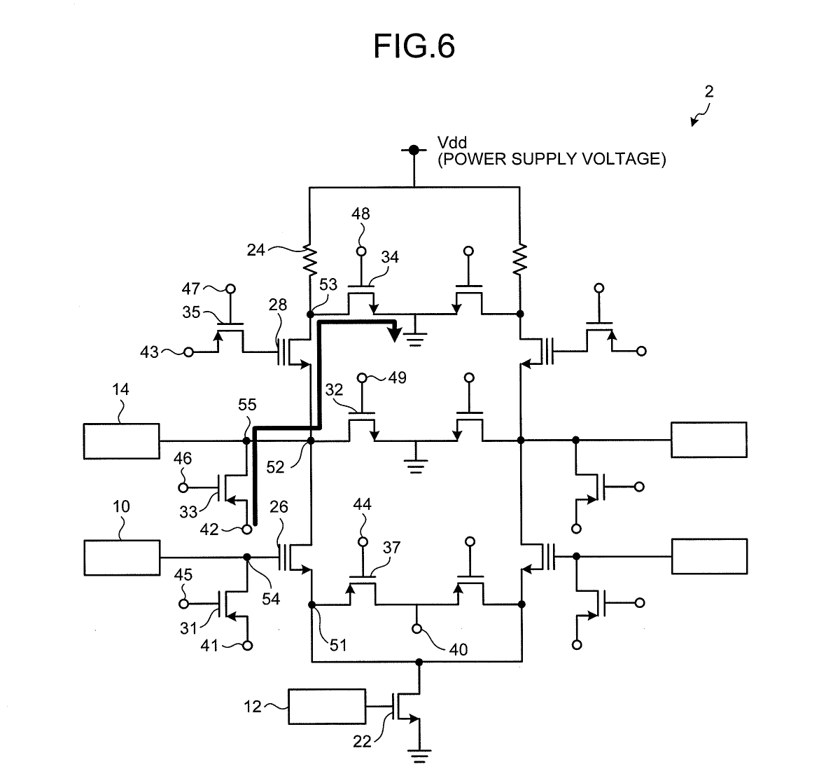

Next, an example of operation for writing (charge storage, threshold voltage adjustment) to the transistor 28 will be described. FIG. 6 is a diagram illustrating the direction of current during writing to the transistor 28. Note that the mixer circuit 2 illustrated in FIG. 6 is the same as the mixer circuit 2 illustrated in FIG. 2, and only one (left side in FIG. 6) of the differential input and the differential output is designated by reference numerals for simplification.

When the power supply voltage (3.3 V, for example) is applied to the node 42 and the node 46 is set to 0 V, the pMOS transistor 33 is turned on and the potential of the nodes 55 and 52 becomes approximately equal to the power supply voltage level. Furthermore, when the power supply voltage is applied to the node 48, the nMOS transistor 34 is turned on and the potential of the node 53 becomes approximately equal to the ground level.

When the power supply voltage is applied to the node 43 and the node 47 is set to 0 V in this state, the pMOS transistor 35 is turned on and voltage approximately equal to the power supply voltage is applied to the gate terminal of the transistor 28. The direction of current at this point is indicated by a thick arrow.

When the transistor 28 operates in this manner, a hot carrier is generated by impact ionization at the drain (on the side of the node 52) of the transistor 28, electrons are trapped in the charge storage layer 65 (FIG. 3) and the threshold voltage Vth (that is, on-resistance) changes. At this point, the voltage applied to the gate terminal of the transistor 28 may be at any level equal to or lower than the power supply voltage and may be changed as appropriate so as to efficiently cause impact ionization.

After changing the threshold voltage Vth of the transistor 28, the operator makes the mixer circuit 2 operate to measure second-order distortion. The operator then adjusts the threshold voltage Vth of the transistor 28 until the second-order distortion during circuit operation of the mixer circuit 2 is reduced to a desired value. In other words, the deterioration in the characteristics due to variation of the load resistors 24-1 and 24-2 can be reduced by adjusting the threshold voltage Vth of at least either one of the transistors 28-1 and 28-2. Note that the adjustment of the threshold voltage Vth is not limited to that by actually measuring the second-order distortion but may be performed by other methods such as by measuring the threshold voltage Vth directly.

As described above, the on-resistance (threshold voltage Vth) changes with the amount of charge stored by the charge storage layer 65, and the value of the threshold voltage Vth is maintained when the amount of charge is maintained. Accordingly, when the mixer circuit 2 operates after the on-resistance is adjusted, potentials that do not allow writing to the charge storage layer 65 of the transistor 28 are set at the nodes 43, 47, 52 and 53. For example, in relation to the transistor 28, a node that is a source is set to 0 V, a node that is a drain is set to 0.1 V, and a node that is a gate is set to 0.8 V.

Although the mixer circuit 2 is described taking the single balanced mixer as an example, the mixer circuit 2 is not limited thereto and may be a double balanced mixer or the like. For example, when the mixer circuit 2 is modified to a double balanced mixer, the input nodes 12 are provided to constitute a differential pair. Accordingly, two nMOS transistors 22 constituting a differential pair may also be replaced by SONOSs so that the threshold voltage Vth thereof can be adjusted.

Next, characteristics of the SONOS will be described in detail. The SONOS has a configuration in which a tunnel film SiO₂ (5 nm), a charge storage layer SiN (5 nm), a block layer (SiO₂; 2 nm+SiN; 2 nm+SiO₂; 2 nm), and a Poly-Si gate electrode are stacked.

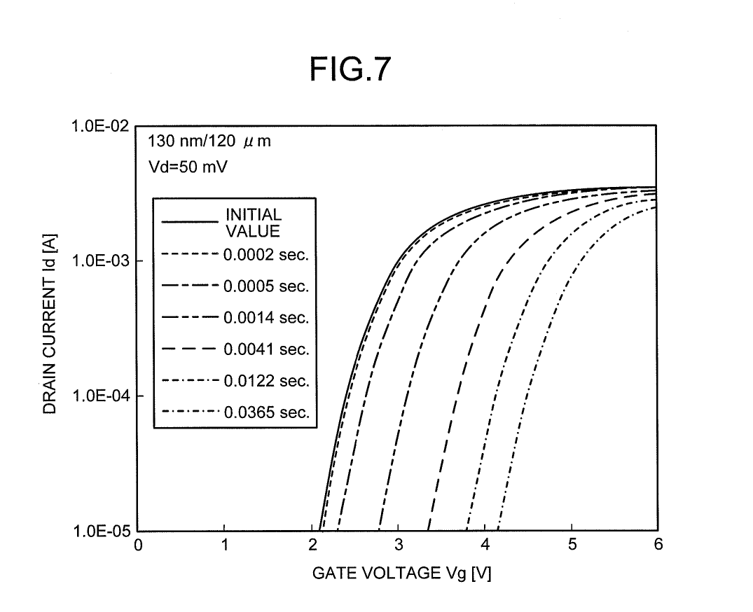

FIG. 7 is a graph illustrating an example of operation of the SONOS (N channel) after the amount of charge stored by a charge storage layer is changed. The amount of charge stored by the charge storage layer is adjusted using the length of time (voltage application time) during which writing is performed on the SONOS. The gate voltage and the drain voltage applied to the SONOS during writing is 3.3 V. In the SONOS, the amount of charge stored in the charge storage layer increases as the voltage application time is longer. In the example illustrated in FIG. 7, the voltage application time is changed from 0 sec. (initial value) to 0.0365 sec. In this case, the gate length L and the gate width W of the SONOS are 130 nm and 120 respectively. Furthermore, in the example illustrated in FIG. 7, the drain voltage Vd of the SONOS is set to 50 mV. In the graph illustrated in FIG. 7, the horizontal axis represents the gate voltage Vg (V) and the vertical axis represents the drain current Id (A) in logarithmic expression so as to express the threshold voltage Vth as a boundary between a weak inversion region and a strong inversion region.

As illustrated in FIG. 7, as the amount of charge stored in the charge storage layer increases, the boundary (threshold voltage Vth) between a weak inversion region in which the drain current exponentially (linearly in FIG. 7) increases with respect to the gate voltage and a strong inversion region in which high drain current flows becomes higher.

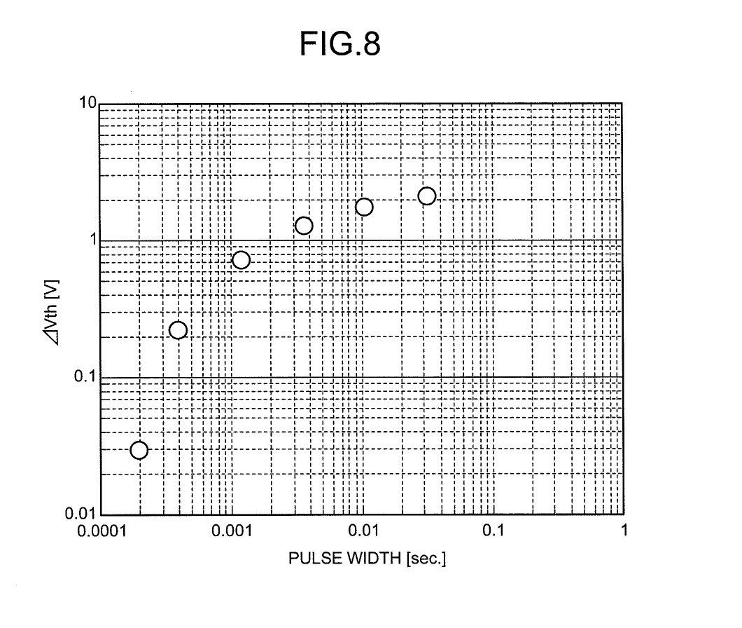

FIG. 8 is a graph illustrating the relationship between a change (ΔVth) in threshold voltage Vth and voltage application time (pulse width) in the result illustrated in FIG. 7. For example, in a case of a transistor in which the gate length is 130 nm or shorter, the change (ΔVth) in the threshold voltage Vth to be adjusted is typically about 30 mV. In FIG. 8, the pulse width corresponding to 30 mV is 2e-4 sec. Thus, if the threshold voltage Vth is to be corrected by 30 mV, the gate voltage and the drain voltage of 3.3 V are applied to the SONGS for 2e-4 sec.

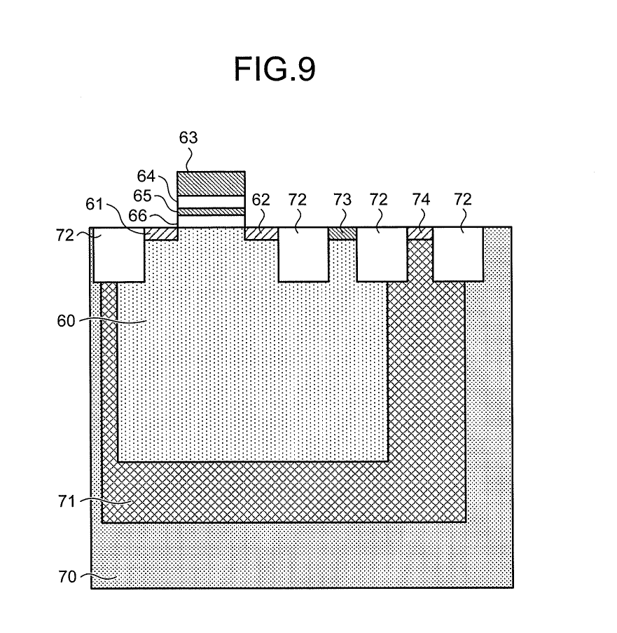

Furthermore, the SONGS may be configured to adjust the amount of charge stored in the charge storage layer by repeating writing and erasing. FIG. 9 is a diagram illustrating an exemplary configuration of an SONGS capable of isolating potentials for each SONGS. As illustrated in FIG. 9, the SONGS may be formed in a triple well structure. Specifically, the SONGS illustrated in FIG. 3 may be formed in a deep n-well 71 formed in a p-type Si substrate 70. The SONGS is individually isolated by STI (shallow trench isolation) 72 on the outside of the source 61 and the drain 62, and a well contact 73 provided in the substrate 60 and a well contact 74 provided in the deep n-well 71 are isolated by STI 72.

Since substrate potentials can be isolated from one another among a plurality of substrates (p-wells) 60 of a plurality of SONOSs structured as illustrated in FIG. 9, it is possible to apply positive bias to the substrate 60 via the well contact 73 and the well contact 74 in each of the SONOSs.

For example, if change (electrons) stored in the charge storage layer of an SONGS after performing writing to the SONGS, positive bias is selectively applied to the substrate 60 on which the SONGS is formed and 0 V is applied to the gate terminal of the SONGS. In other words, it is possible to draw out only electrons stored by the selected SONGS into the substrate 60. In this manner, it is possible to select and perform erasing operation on each of a plurality of SONOSs structured as illustrated in FIG. 9. Furthermore, it is also possible to erase an intended amount of electrons by controlling the time during which the voltage is applied. Accordingly, it is possible to set the threshold voltage Vth of the SONGS illustrated in FIG. 9 to a desired level with higher accuracy by repeating writing and erasure. Furthermore, erasure may be performed by injecting a hot hole generated by an band to band tunneling in a region where the gate and the drain overlap with each other into the charge storage layer by applying 0 V, for example to the gate and 3.3 V, for example to the drain of the SONGS.

Next, a receiving circuit of a communication device in which the mixer circuit 2 is used to reduce deterioration in the characteristics will be described. FIG. 10 is a block diagram illustrating an outline of a receiving circuit 8 of a direct conversion communication device in which the mixer circuit 2 is used. As illustrated in FIG. 10, the receiving circuit 8 includes an antenna 80, a switch 81, a low-noise amplifier (LNA) 82, a phase locked loop (PLL) 83, the mixer circuit 2, a baseband filter 85, a baseband amplifier 86, and an AD converter 87.

The antenna 80 receives a radio wave containing a signal superimposed on a carrier wave. The switch 81 switches a receiving circuit to/from a transmitting circuit that is not illustrated. The LNA 82 amplifies a signal (RF signal) received by the antenna 80 and outputs the amplified signal to the mixer circuit 2. The PLL 83 includes a voltage controlled oscillator (VCO) 84, phase-locks a signal (local signal LO) having a frequency equal to that of the carrier wave, and outputs the resulting signal to the mixer circuit 2.

The mixer circuit 2 mixes the local signal LO output from the PLL 83 and the RF signal output from the LNA 82, and outputs the resulting signal to the baseband filter 85. Although not illustrated in FIG. 10, the mixer circuit 2 receives the local signal LO as differential signals by the differential input nodes 10-1 and 10-2, receives the RF signal output from the LNA 82 by the input node 12, and outputs the differential signals resulting from the mixture from the output nodes 14-1 and 14-2.

The baseband filter 85 receives signals from the mixer circuit 2 and allows a baseband signal to pass therethrough. The process for generating a baseband signal from the differential signals output from the mixer circuit 2 may be performed at any block. The baseband amplifier 86 amplifies the baseband signal. The AD converter 87 converts the baseband signal to a digital signal and outputs the digital signal to a baseband processing circuit that is not illustrated.

According to the mixer circuit according to the embodiment, since the threshold voltage of a transistor can be adjusted from outside, deterioration in the characteristics due to variation of transistors constituting a pair can be reduced.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A mixer circuit comprising:
a plurality of first transistors that is used in a pair and receives a differential signal having a first frequency, the first transistors each having a charge storage layer;
a second transistor that receives a signal having a second frequency;
a group of first nodes that makes the charge storage layer of at least any one of the first transistors store charge during non-operation period during which the differential signal having the first frequency and the signal having the second frequency are not mixed and reduces loss of the charge during operation period during which the differential signal having the first frequency and the signal having the second frequency are mixed, so as to adjust a threshold voltage of at least any one of the first transistors from outside; and
an output node that outputs a signal resulting from mixing the differential signal having the first frequency and the signal having the second frequency.

2. The mixer circuit according to claim 1, further comprising:
a plurality of third transistors that lowers power supply voltage during the operation period applied to each of the first transistors, the third transistors each having a charge storage layer; and
a group of second nodes that makes the charge storage layer of at least any one of the third transistors store charge during the non-operation period and reduces loss of the charge during the operation period, so as to adjust a threshold voltage of at least any one of the third transistors from outside.

3. The mixer circuit according to claim 1, wherein the charge storage layer is an insulating layer.

4. The mixer circuit according to claim 2, wherein the charge storage layer of at least any one of the third transistors is an insulating layer.

5. The mixer circuit according to claim 1, further comprising a plurality of first potential variable units that applies voltage equal to or lower than power supply voltage to a gate terminal of each of the first transistors from outside.

6. The mixer circuit according to claim 5, wherein the first potential variable units are pMOS transistors each having a drain terminal connected to the gate terminal of the first transistor.

7. The mixer circuit according to claim 1, further comprising a plurality of second potential variable units that applies voltage equal to or lower than power supply voltage to a plurality of nodes each connecting each of the first transistors and each of the second transistors.

8. The mixer circuit according to claim 7, wherein the second potential variable units are a plurality of pMOS transistors each having a drain terminal connected to each of a plurality of nodes connecting each of the first transistors and each of the second transistors.

9. The mixer circuit according to claim 1, further comprising a plurality of nMOS transistors each having a drain terminal connected to a drain terminal during the operation period of each of the first transistors.

10. The mixer circuit according to claim 1, further comprising a third potential variable unit that is connected to the output node and applies voltage in a range of ground to power supply voltage from outside.

11. The mixer circuit according to claim 10, wherein the third potential variable unit includes a pMOS transistor having a drain terminal connected to the output node and an nMOS transistor having a drain terminal connected to the output node.

12. The mixer circuit according to claim 1, where in the mixer circuit is included in a semiconductor device.

13. The mixer circuit according to claim 1, where in the mixer circuit is included in a receiving circuit.

14. The mixer circuit according to claim 1, where in the mixer circuit is included in a receiving device that receives a radio wave.

15. The mixer circuit according to claim 1, where in the mixer circuit is included in a communication device that transmits and receives a radio wave.

16. A mixer circuit comprising:
a plurality of first transistors that is used in a pair and receives a differential signal having a first frequency;
a second transistor that receives a signal having a second frequency;
a plurality of third transistors that lowers power supply voltage applied to each of the first transistors during operation period during which the differential signal having the first frequency and the signal having the second frequency are mixed, the third transistors each having a charge storage layer;
a group of nodes that makes the charge storage layer of at least any one of the third transistors store charge during non-operation period during which the differential signal having the first frequency and the signal having the second frequency are not mixed and reduces loss of the charge during the operation period, so as to adjust a threshold voltage of at least any one of the third transistors from outside; and
an output node that outputs a signal resulting from mixing the differential signal having the first frequency and the signal having the second frequency.

17. The mixer circuit according to claim 16, further comprising a plurality of first potential variable units that applies voltage equal to or lower than power supply voltage to a gate terminal of each of the third transistors from outside.

18. The mixer circuit according to claim 17, wherein the first potential variable units are pMOS transistors each having a drain terminal connected to the gate terminal of the third transistor.

19. The mixer circuit according to claim 16, further comprising a second potential variable unit that applies voltage in a range of ground to power supply voltage to the drain terminal during the operation period of each of the third transistors from outside.

20. The mixer circuit according to claim 19, wherein the second potential variable unit is a plurality of nMOS transistors each having a drain terminal connected to a drain terminal during the operation period of each of the third transistors.
